(19) United States
(12) Patent Application Publication
(10) Pub. No.: US 2016/0131731 A1
(43) Pub. Date: May 12, 2016

(54) MAGNETIC RESONANCE IMAGING APPARATUS, MAGNETIC RESONANCE IMAGING METHOD, AND VERSE PULSE COMPRESSION RATE DETERMINATION METHOD

(71) Applicant: HITACHI MEDICAL CORPORATION, Tokyo (JP)

(72) Inventor: Kuniharu OKA, Tokyo (JP)

(73) Assignee: Hitachi Medical Corporation, Tokyo (JP)

(21) Appl. No.: 14/896,982

(22) PCT Filed: May 22, 2014
(86) PCT No.: PCT/JP2014/063540

§ 371 Date: Dec. 9, 2015

(30) Foreign Application Priority Data
Jun. 13, 2013 (JP) 2013-124986

(51) Int. Cl. G01R 33/561; G01R 33/483; G01R 33/28

(52) U.S. Cl. CPC G01R 33/5617; G01R 33/288; G01R 33/4835

(57) ABSTRACT

In order to improve image quality while reducing an SAR regardless of an imaging condition such as a slice position, a phase-encoding amount, and an RF pulse type difference, the VERSE method determines a VERSE pulse compression rate according to the imaging condition. Hence, an imaging sequence generation section generating an imaging sequence by applying an imaging condition to a predetermined pulse sequence and an imaging section executing measurement according to the imaging sequence to reconstruct an image from the obtained echo signal are provided. The pulse sequence includes a VERSE pulse comprised of a high-frequency magnetic field pulse and a slice selective gradient magnetic field pulse. The imaging sequence generation section is provided with a VERSE pulse design part determining a compression rate of the VERSE pulse according to the predetermined imaging condition and applies the determined compression rate to generate the imaging sequence.

### TECHNICAL FIELD

The present invention relates to a magnetic resonance imaging technique and, in particular, to a design technique of a VERSE pulse in imaging using the VERSE (Variable rate selective excitation) method.

### BACKGROUND ART

The VERSE method is a technique for transforming a high-frequency magnetic field (hereinafter, referred to as RF) pulse and a slice selective gradient magnetic field (hereinafter, referred to as Gs) pulse while maintaining the slice profile and power as well as performing imaging in a magnetic resonance imaging apparatus (hereinafter, referred to as an MRI apparatus). For example, the method is used for reducing a Specific Absorption Rate (SAR) per unit weight that is an index of heat generated to an object by an RF pulse. Hereinafter, a combination of the RF pulse and the Gs pulse to be transformed is referred to as a VERSE pulse.

Since the SAR is proportional to a square of an amplitude, the SAR is reduced by reducing the maximum value of an RF pulse amplitude. Therefore, in the VERSE method, a band width is expanded in the time direction by reducing the amplitude in a portion where the RF pulse amplitude is large and is shortened in the time direction by increasing the amplitude in a portion where the amplitude is small in order to transform the RF pulse shape, which achieves an RF pulse with a small amplitude while maintaining an application time.

However, when transforming a VERSE pulse, a lot of non-linear portions are generated in a Gs pulse that is being excited, which can easily cause an input/output error by response performance of a gradient magnetic field amplifier and an error by an overcurrent. Hence, a slice profile collapse and an excitation position shift are easily caused.

As a technique for reducing an input/output error of a gradient magnetic field pulse, a technique for calculating the input/output error from an actually measured value to reflect it when a VERSE pulse waveform is determined can be used (for example, refer to Patent Literature 1). This technique executes a sequence for calculating a shape of the gradient magnetic field pulse in advance of main imaging in order to actually measure the shape of the gradient magnetic field pulse and derives the input/output error from the result.

There is also a method where an input/output relationship is expressed in a transfer function based on a result of the gradient magnetic field pulse measured actually by the sequence for calculating the shape of the gradient magnetic field pulse in order to derive and use an input/output error from an output waveform calculated by applying the transfer function to an input waveform.

### CITATION LIST

### Patent Literature

PTL 1: International Publication No. 2013/002231

### SUMMARY OF INVENTION

### Technical Problem

However, in the method of obtaining an input/output error of a gradient magnetic field pulse from an actually measured value, the actual measurement is required each time imaging is performed because a shape of the gradient magnetic field pulse differs depending on the imaging condition. Also, addition needs to be increased to enhance an accuracy of the actually measured value due to using the value as is, which results in a long imaging time. Additionally, in order to consider a slice position effect and oblique effect, a shape of the gradient magnetic field pulse needs to be measured actually in a plurality of positions and angles.

Also, the method using the transfer function can obtain a stable result without extending the imaging time as described above. However, an error remains because a waveform when a transfer function is derived is different from that used actually, which cannot completely remove a problem caused by an input/output error.

An error effect of a gradient magnetic field pulse becomes more noticeable as being distant from the magnetic field center. Therefore, excitation does not occur in a correct position as being distant from the magnetic field center. That is, it is easy to receive an off-resonance effect. Therefore, in case of multi-slice imaging, slice profiles are different in each slice, and cross-talk effects are different in each slice. Additionally, for example, in case of a spin echo sequence or the like, if Gs pulses applying in different RF pulse types (an excitation pulse and refocus pulse) are the same, an undesired portion is excited and refocused in a region where a gradient magnetic field pulse is not linear, and then artifacts are generated from the portion.

The present invention was made in light of the above problems and has a purpose to provide a technique for improving image quality while reducing an SAR regardless of imaging conditions such as a slice position, a phase-encoding amount, and a difference between RF pulse types.

### Solution to Problem

The present invention determines a VERSE pulse compression rate according to the imaging conditions in the VERSE method. The imaging conditions are, for example, a phase-encoding amount (off-center amount) to be applied immediately after a VERSE pulse, a distance from the magnetic field center of a slice position, an RF pulse type (excitation pulse and refocus pulse), and the like.

### Advantageous Effects of Invention

Image quality is improved while reducing an SAR regardless of imaging conditions such as a slice position, a phase-encoding amount, and a difference between RF pulse types.

### BRIEF DESCRIPTION OF DRAWINGS

FIG. 1 is an overall configuration diagram of the MRI apparatus of the first embodiment.

FIG. 2 is a functional block diagram of the main control unit of the first embodiment.

FIG. 3 is an explanatory diagram explaining an example of the imaging parameter setting screen of the first embodiment.

FIGS. 4(a) to 4(i) are explanatory diagrams explaining a relationship between the RF pulse shape, the Gs pulse shape, and the slice profile of the first embodiment.

FIGS. 5(a) to 5(d) are explanatory diagrams explaining the changing states of a compression rate of the first embodiment.

FIGS. 6(a) to 6(c) are explanatory diagrams explaining examples of the VERSE pulse compression of the first embodiment.

FIG. 7 is an explanatory diagram explaining an example of the other VERSE pulse compression of the first embodiment.

FIG. 8 is a flow chart of the imaging process of the first embodiment.

FIGS. 9(a) to 9(d) are explanatory diagrams explaining the changing states of a compression rate of the second embodiment.

FIGS. 10(a) to 10(d) are explanatory diagrams explaining examples of the VERSE pulse compression of the second embodiment.

FIG. 11 is a flow chart of the imaging process of the second embodiment.

FIGS. 12(a) and 12(b) are explanatory diagrams explaining the VERSE pulse compression method of the third embodiment.

FIG. 13 is an explanatory diagram explaining an example of the VERSE pulse compression of the third embodiment.

FIG. 14 is a flow chart of the imaging process of the third embodiment.

FIG. 15 is an explanatory diagram explaining an example of the other VERSE pulse compression of the third embodiment.

FIG. 16 is an explanatory diagram explaining an example of the VERSE pulse compression in a case where the methods of the first embodiment and the second embodiment are combined.

FIG. 17 is a flow chart of the imaging process in a case where the methods of the first embodiment, the second embodiment, and the third embodiment are combined.

### DESCRIPTION OF EMBODIMENTS

### First Embodiment

Hereinafter, the first embodiment of the present invention will be described in detail according to the attached diagrams. Additionally, in all the diagrams for explaining the embodiments of the invention, unless otherwise mentioned, the same symbols are provided for the same functions, and the repeated explanations are omitted.

In the present embodiment, a deformation rate (compression rate) of a VERSE pulse is adjusted according to the imaging condition in imaging by the VERSE method. Hence, a slice profile collapse and an off-resonance effect caused by a difference in error or intensity of a slice selective gradient magnetic field (a Gs pulse) is improved to obtain an image with a better SNR and a better contrast while the VERSE effect is being obtained.

In particular, multi-slice imaging by the VERSE method is a target of the present embodiment, a slice profile collapse caused by an error of a Gs pulse and the like is mitigated to obtain a high-quality image regardless of a distance from the magnetic field center of a slice position by changing a VERSE pulse compression rate waveform as an imaging condition according to the slice position.

<Apparatus Configuration>

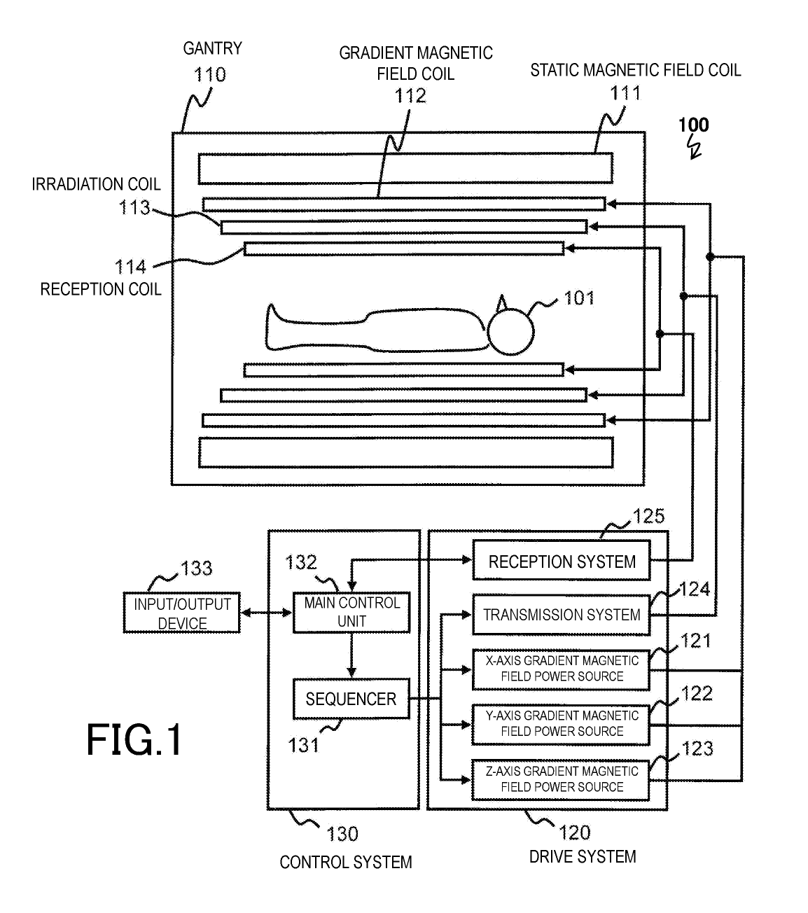

First, the configuration of the MRI apparatus of the present embodiment will be described. FIG. 1 is an overall schematic configuration diagram of the MRI apparatus 100. The MRI apparatus 100 of the first embodiment is comprised of the gantry 110, the drive system 120, and the control system 130.

In the gantry 110, the static magnetic field coil 111, the gradient magnetic field coil 112, the irradiation coil 113, and the reception coil 114 are disposed. The static magnetic field coil 111 is composed with a super conductive coil or normal conductive coil and provides a static magnetic field to a space for placing the object 101. The gradient magnetic field coil 112 provides gradient magnetic fields to the object 101 in the three axis directions X, Y, and Z direct to each other. The irradiation coil 113 repeatedly applies a high-frequency magnetic field (RF) pulse that causes an NMR phenomenon to atomic nuclei of atoms composing living tissues of the object 101 according to the imaging sequence to be described later. The reception coil 114 receives an echo signal emitted by the NMR phenomenon.

The drive system 120 is comprised of the X-axis gradient magnetic field power source 121, the Y-axis gradient magnetic field power source 122, the Z-axis gradient magnetic field power source 123, the transmission system 124, and the reception system 125. The X-axis gradient magnetic field power source 121, the Y-axis gradient magnetic field power source 122, and the Z-axis gradient magnetic field power source 123 respectively drives the gradient magnetic field coil 112. The transmission system 124 irradiates an RF pulse to the irradiation coil 113. The reception system 125 transmits an echo signal received in the reception coil 114 to the main control unit 132.

The control system 130 is comprised of the sequencer 131 and the main control unit 132. The sequencer 131 drives X-axis gradient magnetic field power source 121, the Y-axis gradient magnetic field power source 122, the Z-axis gradient magnetic field power source 123, and the transmission system 124 according to the command from the main control unit 132. Also, the main control unit 132 drives the reception system 125.

The main control unit 132 includes a CPU, a memory, a storage device, and the like, generates an imaging sequence from an imaging parameter (imaging condition) set by a user and a pulse sequence, and then provides commands to the sequencer 131 according to the imaging sequence.

A gradient magnetic field in a pulse sequence (imaging sequence) is regulated by the logical axes of Slice (Gs), Phase (Gp), and Frequency (Gf). The main control unit 132 converts these into the physical axes (Gx, Gy, and Gz) of X, Y, and Z to control the gradient magnetic field power sources 121, 122, 123 of the respective axes.

A gradient magnetic field on logical axes is a pulse having a trapezoid shape normally by taking time as a horizontal axis respectively. In the following description, pulses on the respective logical axes are generically named as a gradient magnetic field pulse, and it does not matter on which logical axis the pulse is.

Also, the main control unit 132 of the present embodiment performs an image reconstruction process for performing image reconstruction calculation using an echo signal detected by the reception system 125 and a process to support setting of an imaging parameter by a user (imaging parameter setting support process) in addition to a measurement control process for driving and controlling the drive system 120 through the sequencer 131. Also, in the measurement control process, a VERSE pulse shape is determined according to the slice position. The processes and functions of the main control unit 132 will be described in detail later.

Additionally, the main control unit 132 is connected to the input/output device 133 receiving inputs from a user and presenting the process results by the main control unit 132 to the user. The input/output device 133 is comprised of, for example, an operation console, a display, and the like that receive commands from a user. It may be configured so that a Graphical User Interface (hereinafter, referred to as GUI) is displayed on the display to receive inputs from a user.

<Function of Main Control Unit>

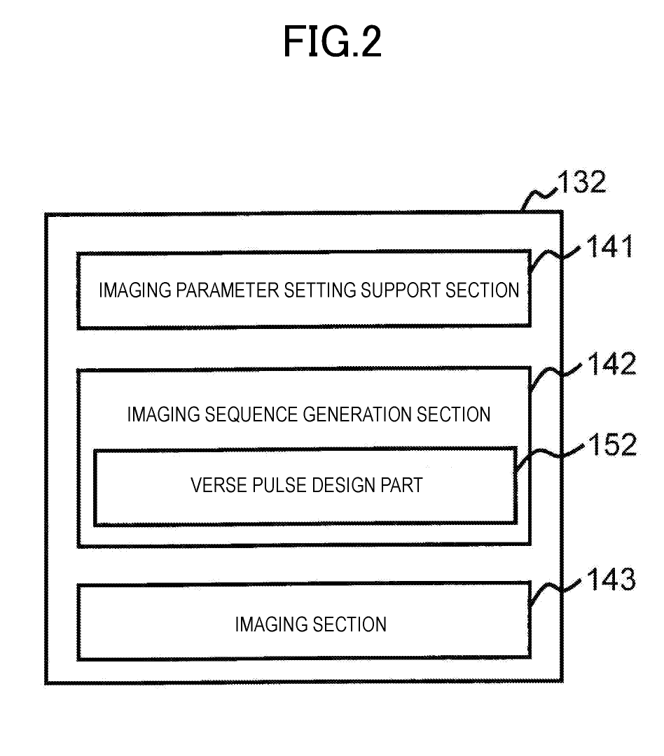

The main control unit 132 of the present embodiment achieves the above functions. Therefore, as shown in FIG. 2, the main control unit 132 of the present embodiment includes the imaging parameter setting support section 141, the imaging sequence generation section 142, and the imaging section 143. The CPU realizes these functions of the main control unit 132 by loading the program stored in advance in the storage device into the memory to execute the program.

The imaging parameter setting support section 141 supports setting of an imaging parameter by a user.

Specifically, when a user activates the MRI apparatus 100, the imaging parameter setting support section 141 displays an imaging parameter setting screen on the display of the input/output device 133 to receive inputs from the user. The imaging parameter setting screen is a GUI, and, for example, a mode of displaying a pop-up window interactively is used for the input.

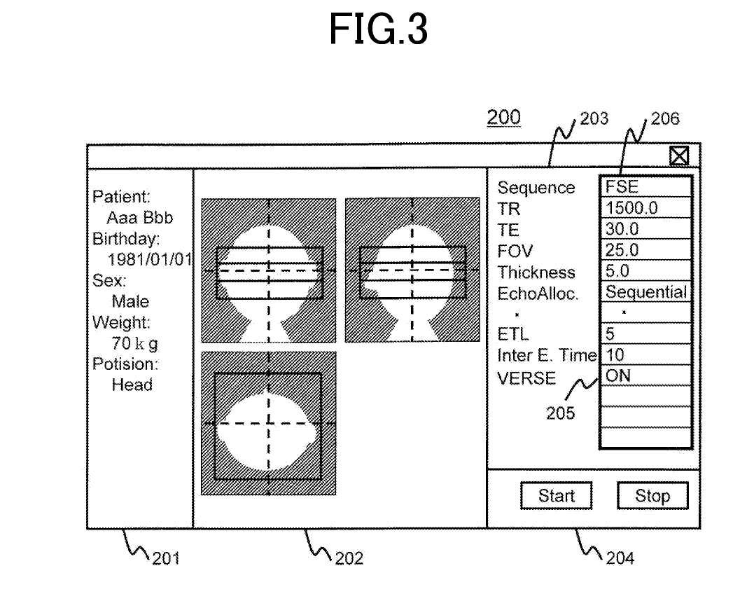

FIG. 3 shows the imaging parameter setting screen 200 to be displayed on the display of the input/output device 133. The imaging parameter setting screen 200 is comprised of the patient information display region 201, the first input region 202 for inputting imaging parameters by graphic operation, the second input region 203 for inputting imaging parameters by direct value input, and the imaging control region 204.

The first input region 202 and the second input region 203 are regions for receiving inputs and changes of imaging parameters. A user can change an imaging parameter such as movement and rotation of a slice cross section position by operating a parameter input auxiliary graphic displayed on the first input region 202.

In the present embodiment, commands of at least a pulse sequence type to be used for an imaging sequence and whether or not to use the VERSE method are received as an imaging parameter. Therefore, the second input region 203 includes the VERSE command region 205 for receiving a command of whether or not to use the VERSE method and the sequence receiving region 206 for receiving an input of a pulse sequence type to be used for an imaging sequence.

When a command to use the VERSE method (VERSE ON) is received from a user through the VERSE command region 205, the imaging sequence generation section 142 to be described later designs a VERSE pulse.

The imaging control region 204 sets an imaging parameter input through the imaging parameter setting screen 200 and is provided with a start button for receiving a command to start imaging.

Additionally, the imaging parameter setting support section 141 may be configured so that recommended parameter values are retained in advance according to each pulse sequence and are displayed respectively when a pulse sequence is selected by a user through the sequence receiving region 206. In this case, the user changes the displayed recommended parameter value accordingly.

The imaging sequence generation section 142 of the present embodiment generates an imaging sequence by applying an imaging parameter to a predetermined pulse sequence. The imaging parameter input by a user through the above imaging parameter setting screen 200 are used.

Additionally, a pulse sequence to be used for imaging in the present embodiment is a sequence for multi-slice imaging that includes one or more VERSE pulses. The imaging sequence generation section 142 of the present embodiment is provided with the VERSE pulse design part 152 determining a VERSE pulse compression rate according to the predetermined imaging condition when a user commands to perform imaging using the VERSE method.

Imaging conditions include, for example, a slice position, a phase-encoding amount, a flip angle (pulse type) of an RF pulse, and the like. The functions of the VERSE pulse design part 152 will be described in detail later. The imaging sequence generation section 142 compresses a VERSE pulse at a determined compression rate to generate an imaging sequence.

In the present embodiment, as an imaging condition, a position of a slice (a slice position) selected using an RF pulse and a Gs pulse composing a VERSE pulse is used. The VERSE pulse design part of the present embodiment reduces a compression rate as the slice position becomes farther from the magnetic field center.

The imaging section 143 provides a command to the sequencer 131 so as to drive and control the drive system 120 according to the imaging sequence generated by the imaging sequence generation section 142 and reconstructs an image from an echo signal received by the reception system 125 according to the imaging sequence.

<Compression Rate>

Next, a determination method of a VERSE pulse compression rate using the VERSE pulse design part 152 of the present embodiment will be described. Additionally, in the present description, the compression rate K is calculated using a value before deformation and a value after the deformation by the VERSE method of an amplitude at the peak (peak amplitude) of an RF pulse.

Specifically, taking a peak amplitude before deformation as Apa and a peak amplitude after the deformation as Apb, the compression rate K is a value between 0 and 100 that is expressed in the formula K=((Apa−Apb)/Apa)×100, and the unit is %. That is, as the peak amplitude of an RF pulse is deformed smaller, the compression rate K becomes larger.

Prior to describing the compression rate determination method of the present embodiment, the adjustment method of a VERSE waveform in the VERSE method will be described. As described above, a VERSE pulse is comprised of an RF pulse and a Gs pulse. In the present embodiment, an amplitude and an application time of these VERSE pulses are changed. At this time, the pulses are expanded/contracted and changed so that the area is constant.

For example, in a case where SAR reduction is a purpose, a peak amplitude of an RF pulse needs to be reduced. Therefore, in this case, an amplitude of a high-amplitude portion of an RF pulse is reduced, and an amplitude of a low-amplitude portion is increased accordingly. This realizes excitation being a similar slice profile without changing a power and an application time.

Also, a Gs pulse changes an amplitude of a portion corresponding to an RF pulse at the same rate according to the change of the said RF pulse. Additionally, it is configured so that no input/output error occurs for the Gs pulse as possible by considering performance of the RF pulse amplifier provided with the transmission system 124 and the gradient magnetic field amplifier provided with the gradient magnetic field power sources 121, 122, and 123, the error effect thereof, as well as responsiveness of a gradient magnetic field pulse.

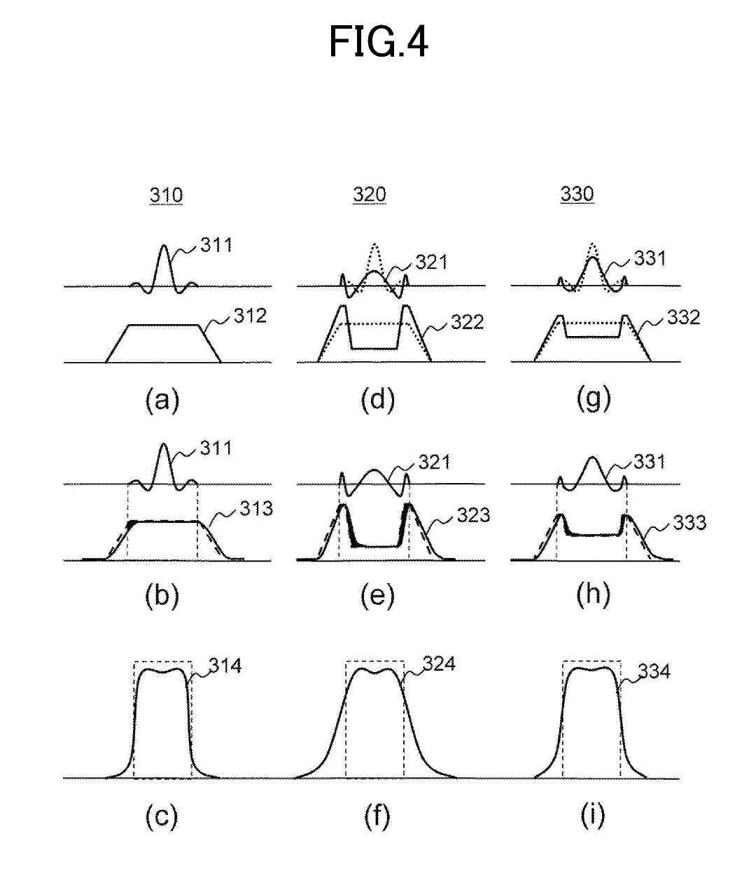

FIG. 4 is a diagram for explaining a relationship between an RF pulse shape, a Gs pulse shape, and a slice profile. The case 310 shown in FIGS. 4(a) to 4(c) is an example in case of not performing deformation by the VERSE method. That is, it is a case of the compression rate K1=0. The RF pulse and the Gs pulse in case of not performing deformation by the VERSE method are expressed as 311 and 312 respectively.

However, the Gs pulse 312 is an input waveform and a shape in an ideal state. But, the above various errors are included, and the actual output waveform is like the output Gs pulse 313 shown in FIG. 4(b). Additionally, a portion of a difference between the Gs pulse 312 and the output Gs pulse 313 is shown in black.

In the case 310, the portion where a difference is generated between the shapes of the Gs pulse 312 and the output Gs pulse 313 corresponds to the portion other than the peak of the RF pulse 311. That is, it is a high range portion of irradiation. Therefore, as shown in FIG. 4(c), the collapse of the shape of the slice profile 314 is small.

The cases 320 and 330 are examples in case of performing deformation by the VERSE method. This is a case where the compression rate K2 of the case 320 is larger than the compression rate K3 of the case 330.

FIG. 4(d) shows the input waveforms of the RF pulse 321 and the Gs pulse 322 designed by setting the compression rate to K2. Here, the undeformed RF pulse 311 and Gs pulse 312 are shown in dotted lines. Thus, even in a case where a VERSE pulse was compressed, various errors are included in a Gs pulse, and the actual output shape is like the output Gs pulse 323 shown in FIG. 4(e). Here, a portion of a difference between the Gs pulse 322 and the output Gs pulse 323 is also shown in black.

In the case 320, a shape difference between the Gs pulse 322 and the output Gs pulse 323 is large, and the portion where the difference is generated is in the vicinity of the peak portion of the RF pulse 321. Thus, an error is included also in a low range portion of irradiation, and the shape of the slice profile 324 is greatly collapsed as shown in FIG. 4(f) in the case 320.

FIG. 4(g) shows the input waveforms of the RF pulse 331 and the Gs pulse 332 designed by setting the compression rate to K3. Here, the undeformed RF pulse 311 and Gs pulse 312 are shown in dotted lines. Thus, even in a case where a VERSE pulse was compressed, various errors are included in a gradient magnetic field pulse, and the actual output shape is like the output Gs pulse 333 shown in FIG. 4(h). Here, a portion of a difference between the Gs pulse 332 and the output Gs pulse 333 is also shown in black.

In the case 330 where the compression rate K3 is smaller than the compression rate K2 of the case 320, a shape difference between the Gs pulse 332 and the output Gs pulse 333 is small compared to the case 320, and the portion where the difference is generated becomes farther from the peak portion of the RF pulse 321 compared to the case 320.

Therefore, as shown in FIG. 4(i), the collapse of the shape of the slice profile 334 is small compared to the case 320.

Thus, an error between an input shape and an output shape of a Gs pulse becomes large, and in addition, the point where the large error is generated is near the peak of an RF pulse (a low range portion of irradiation) when a VERSE pulse compression rate is high. Therefore, in case of a high compression rate of the VERSE pulse, a slice profile is collapsed, which easily deteriorates an image because excitation is performed for tissue in a different position from that originally intended.

<Compression Method>

The VERSE pulse design part 152 of the present embodiment determines a VERSE pulse compression rate (an RF pulse and a Gs pulse) so as to excite tissue in a target position as possible regardless of a slice position when compressing the VERSE pulse for SAR reduction.

Generally, the linearity of a Gs pulse is maintained in the vicinity of the magnetic field center and is not maintained according to the distance from the magnetic field center. As being distant from the magnetic field center, a magnetic field is distorted, which affects the linearity. Thus, in a region separated from the magnetic field center in the application direction of the Gs pulse, excitation is performed for tissue in a different position from that originally intended, and signals from the portion becomes artifacts.

Therefore, the VERSE pulse design part 152 of the present embodiment determines a compression rate of each VERSE pulse in a pulse sequence according to the distance from the magnetic field center of a slice position excited by the said VERSE pulse. Specifically, a compression rate of an RF pulse in a slice position nearest to the magnetic field center becomes the largest, and a compression rate of the RF pulse is reduced as the slice position becomes farther from the magnetic field center. At this time, a Gs pulse to be applied simultaneously is also deformed.

Because an error between an input shape and an output shape of a Gs pulse is small in the vicinity of the magnetic field center, the effect is small even at a high compression rate. On the other hand, because an error of the Gs pulse becomes large as being distant from the magnetic field center, the effect is minimized by reducing a compression rate. Thus, a VERSE compression rate is determined to maintain a slice profile shape regardless of a distance from the magnetic field center of a slice position in the present embodiment. Hence, approximately equivalent slice profiles are realized in all the slices while maintaining the effect by VERSE such as SAR reduction to some extent.

Additionally, a compression rate is set so as to be simply reduced according to the distance from the magnetic field center of each slice. At this time, the compression rate may be changed according to the slice position between predetermined maximum and minimum compression rates.

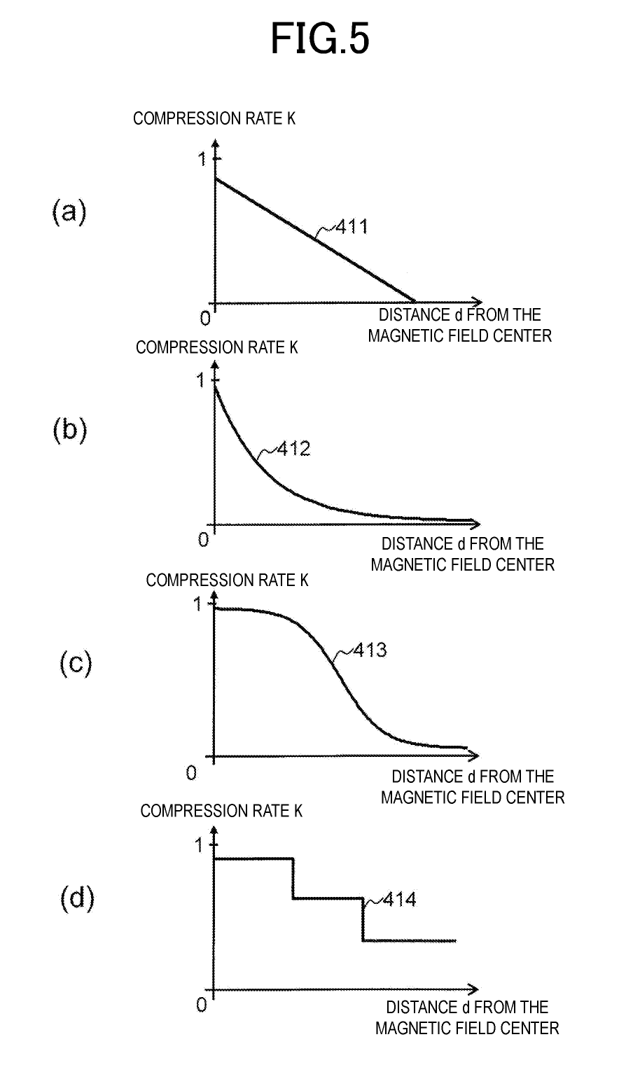

The simple reduction may be, for example, linear shown in the graph 411 of FIG. 5(a). That is, a compression rate change amount between slice positions is set so as to be constant. Also, as shown in the graph 412 of FIG. 5(b), a compression rate change rate between slice positions may be set so as to be constant. Additionally, as shown in the graph 413 of FIG. 5(c), a compression rate may be changed along a predetermined curve so that shapes of slice profiles obtained in each slice position satisfy a certain criterion.

For example, because an error effect is small in the vicinity of the magnetic field center, a compression rate is changed gently, and a compression rate change amount is increased gradually from a region where the error effect starts to appear. Then, the compression rate may be set so as to transition at a low level from a region where the error effect exceeds a predetermined criterion. Also, a compression rate may be configured so as to change stepwise according to the slice position. That is, as shown in the graph 414 of FIG. 5(d), it may be configured so that compression rates in several stages are determined in advance for applying one of the compression rates. In this case, a two-stage compression rate may be used.

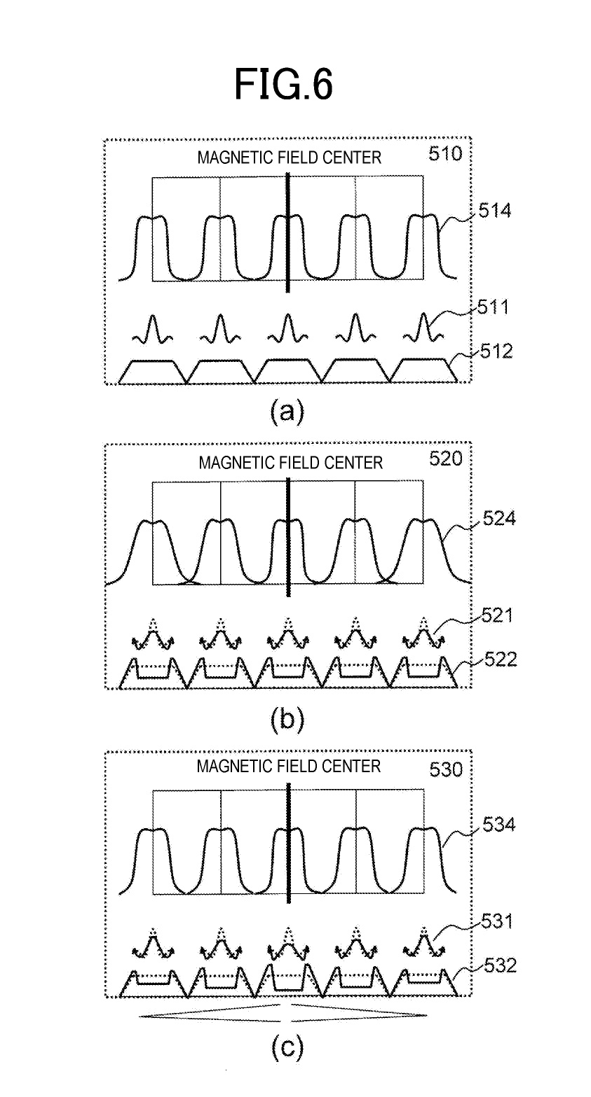

Next, a concrete example of a VERSE pulse designed by the VERSE pulse design part 152 of the present embodiment will be described. FIGS. 6(a) to 6(c) are diagrams for explaining examples of VERSE pulse compression by the VERSE pulse design part 152 of the present embodiment. Here, a case where the slice number Ns of multi-slice measurement is 5 is shown as an example. The slice number Ns is not limited to this.

FIG. 6(a) shows the case 510 including the RF pulse 511 whose compression rate is 0 i.e., an ideal initial setting and the Gs pulse 512 as well as the slice profile 514 by these pulses. In the case 510, the slice profile 514 is approximately equivalent in all the slices regardless of a slice position.

FIG. 6(b) shows an example (the case 520) in which a VERSE pulse compression rate is set to a certain value other than 0 regardless of a slice position. In this case, as a slice position becomes farther from the magnetic field center, an error effect of the Gs pulse 522 becomes conspicuous, which collapses a shape of the slice profile 524. In a separated position from the magnetic field center, the collapse of the shape of the slice profile 524 becomes larger, which deteriorates an image. Also, as shown in the present diagram, a cross-talk effect varies between the vicinity of the magnetic field center and a position separated from the magnetic field center. Thus, a difference of image quality between slices is caused in the case 520.

FIG. 6(c) shows a VERSE pulse compression example (the case 530) of the present embodiment. As described above, a compression rate is changed according to the slice position in the present embodiment. In the vicinity of magnetic center, the compression rate is increased to the maximum, which greatly deforms the RF pulse 531 and the Gs pulse 532. On the other hand, as being distant from the center, the compression rate is reduced, which makes deformation of these pulses smaller.

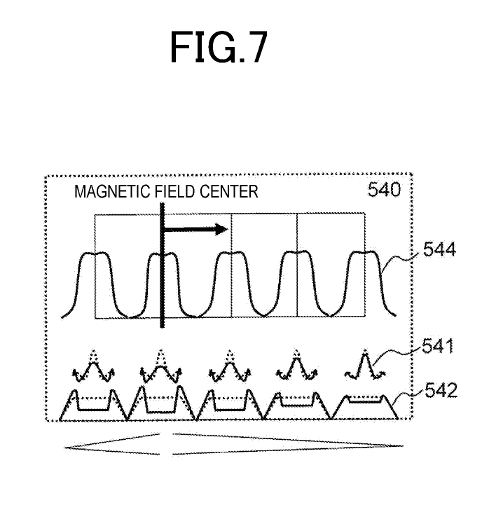

Additionally, an example of the case in which the case 530 is off-centered by 1 slice in the slice direction is shown in FIG. 7 (the case 540). Also in this case, similarly to the case 530, a VERSE pulse compression rate is reduced according to the distance from the magnetic field center in each slice position.

<Imaging Process Flow>

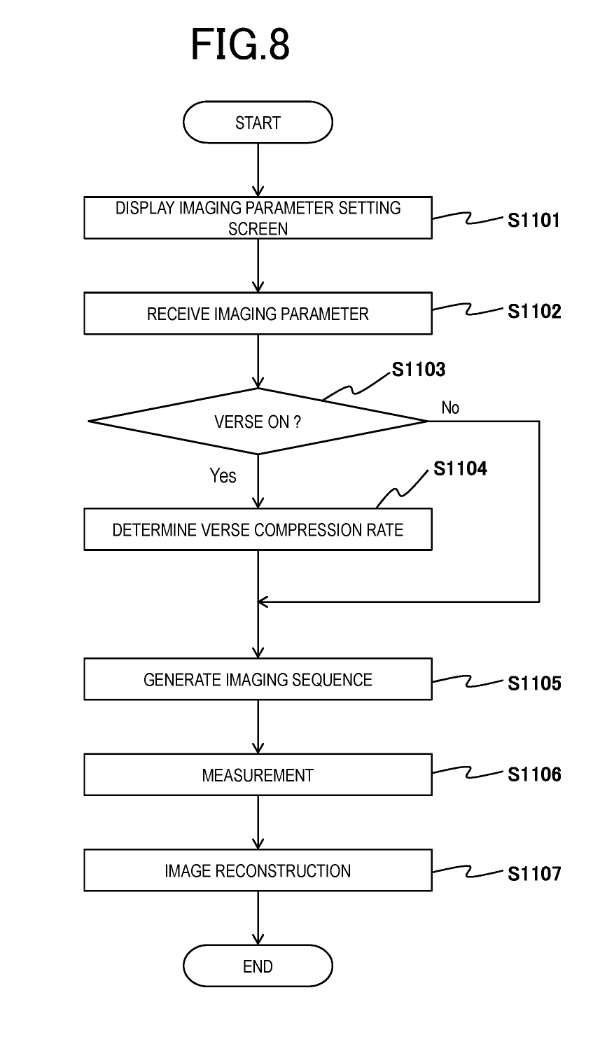

Lastly, an imaging process flow by the main control unit 132 of the present embodiment will be described. FIG. 8 is a process flow of the imaging process of the present embodiment. The imaging process of the present embodiment starts after a start-up command by a user.

After receiving the start-up command by a user, the imaging parameter setting support section of the present embodiment displays the imaging parameter setting screen 200 on the display of the input/output device 133 (Step S1101).

When receiving a command to start imaging from a user, the imaging sequence generation section 142 receives an imaging parameter input by the user through the imaging parameter setting screen 200 (Step S1102). Then, whether or not a command to use the VERSE method for imaging is received (VERSE ON or OFF) is determined (Step S1103).

In case of VERSE ON, the imaging sequence generation section 142 allows the VERSE pulse design part 152 to determine a VERSE pulse compression rate identified with an imaging parameter input by a user (Step S1104) and reflects the determination results to generate an imaging sequence (Step S1105).

On the other hand, in case of VERSE OFF in Step S1103, the imaging sequence generation section 142 proceeds to Step S1105 and uses shapes of an RF pulse and a Gs pulse identified with an imaging parameter input by a user as is to generate an imaging sequence.

The imaging section 143 provides commands to the sequencer 131 according to the generated imaging sequence, executes measurement (Step S1106), and then reconstructs an image from an echo signal obtained by the measurement (Step S1107). Then, the main control unit 132 ends the imaging process.

As described above, the MRI apparatus 100 of the present embodiment is provided with the imaging sequence generation section 142 that generates an imaging sequence by applying an imaging condition to a predetermined pulse sequence and the imaging section 143 that executes measurement according to the imaging sequence to reconstruct an image from the obtained echo signal, the pulse sequence includes a VERSE (Variable rate selective excitation) pulse comprised of a high-frequency magnetic field pulse and a slice selective gradient magnetic field pulse, and the imaging sequence generation section 142 is provided with the VERSE pulse design part 152 that determines a compression rate of the VERSE pulse according to the predetermined imaging condition and applies the determined compression rate when generating the imaging sequence.

At this time, the imaging condition is a slice position selected by the VERSE pulse, and the VERSE pulse design part 152 determines a compression rate of the VERSE pulse selecting a slice position whose distance from the magnetic field center is a first distance so that the compression rate is smaller than a compression rate of the VERSE pulse selecting a slice position of a second distance whose distance from the said magnetic field center is closer than the first distance. For example, as the slice position becomes farther from the magnetic field center, the compression rate becomes smaller.

Thus, imaging is performed by changing a VERSE pulse compression rate according to the slice position in the present embodiment. At this time, the compression rate is determined so as to obtain approximately equivalent slice profile shapes in each slice position. Therefore, image quality change according to the slice position is reduced. Hence, regardless of a distance from the magnetic field center, equivalent slice profile images can be provided, and problems such as image quality deterioration due to a position and different cross-talk effects between slices can be reduced. Also, because an amplitude of an RF pulse can be greatly reduced in the magnetic field center, an SAR reduction effect is large.

### Second Embodiment

Next, the second embodiment of the present invention will be described. In the first embodiment, a VERSE pulse compression rate is determined according to the slice position. In the present embodiment, a VERSE pulse compression rate is determined according to the phase-encoding amount.

The MRI apparatus of the present embodiment has a basically similar configuration to the MRI apparatus 100 of the first embodiment. However, because the condition to determine a VERSE pulse compression rate is different as described above, the imaging sequence generation section 142 performs different processes. Hereinafter, different configurations from the first embodiment will be mainly described for the present embodiment.

The imaging sequence generation section 142 of the present embodiment, similarly to the first embodiment, generates an imaging sequence by applying an imaging parameter to a predetermined pulse sequence. The imaging parameter is input by a user through the above imaging parameter setting screen 200 before the use.

The imaging sequence generation section 142 of the present embodiment, similarly to the first embodiment, includes the VERSE pulse design part 152 that determines a VERSE pulse compression rate according to the predetermined imaging condition in a case where a user specifies a measurement by the VERSE method (VERSE ON). In the present embodiment, an imaging condition is a phase-encoding amount to be applied immediately after a VERSE pulse. The VERSE pulse design part 152 of the present embodiment determines a VERSE pulse compression rate for each phase encoding. At this time, a compression rate of the VERSE pulse immediately before applying a first of the phase-encoding amount is determined so that the compression rate is larger than a compression rate of the VERSE pulse immediately before applying a second phase-encoding amount smaller than the first phase-encoding amount. For example, the larger the phase-encoding amount, the larger the compression rate becomes.

This is because a large effect is caused in image quality by an echo signal disposed in a low-frequency region of k-space compared to an echo signal disposed in a high-frequency region of k-space. Therefore, the VERSE pulse design part 152 of the present embodiment reduces a compression rate and suppresses a shape change of a Gs pulse for an echo signal to be disposed in a low-frequency region of k-space (k-space center). On the other hand, the VERSE pulse design part 152 increases a compression rate and reduces an SAR for an echo signal to be disposed in a high-frequency region of k-space.

A compression rate is set so as to simply increase according to the phase-encoding amount. At this time, the minimum and maximum compression rates may be determined in advance to change a compression rate according to the phase-encoding amount within the range. For example, a gradient magnetic field amplitude determines how large the error effect is. Using this, an allowable maximum compression rate may be determined.

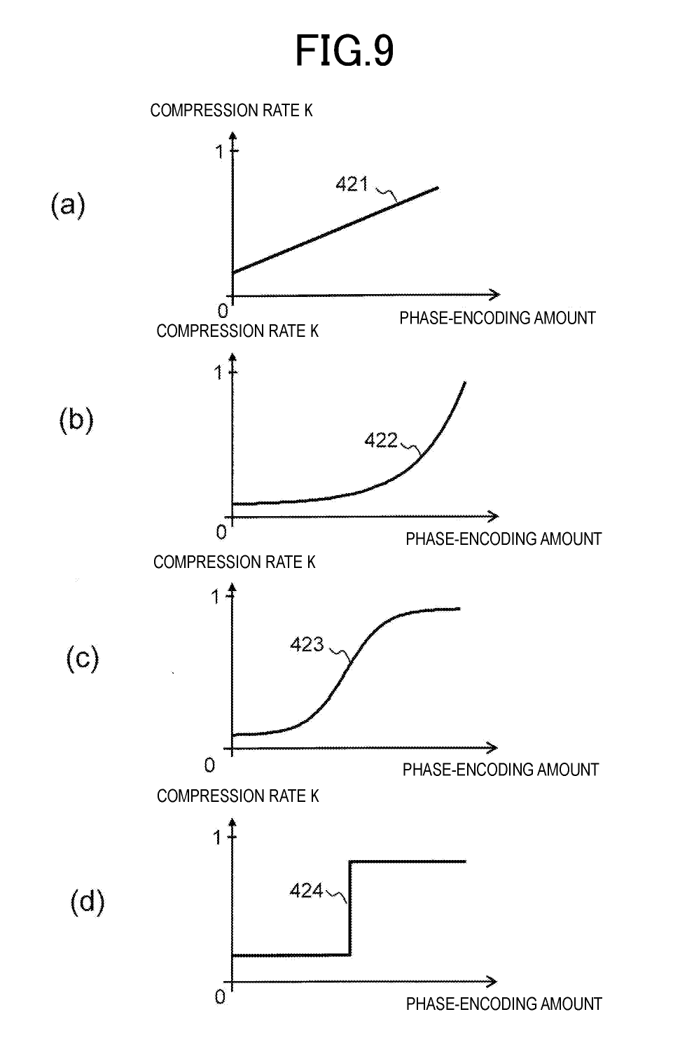

The simple increase may be, for example, linear shown in FIG. 9(a). That is, a constant change amount is set for a compression rate among phase-encoding steps. For example, the change amount is calculated by setting compression rates on both the ends of k-space and performing division with a matrix size (resolution). Also, as shown in FIG. 9(b), a change rate of a compression rate between phase-encoding steps may be determined so as to be constant. Also, as shown in FIG. 9(c), a compression rate may be changed along a predetermined curve so that a certain criterion is satisfied for effectivity on off-resonance and the like caused by each phase-encoding amount. For example, a compression rate is changed at a low value in the vicinity of the k-space center having a large effect on image quality, a compression rate is changed at a high value in an end of k-space having a small effect, and a compression rate is changed smoothly according to the criterion in the other portions. Also, it may be configured so that a compression rate changes stepwise according to the phase-encoding amount. For example, as shown in FIG. 9(d), it may be configured so that two compression rates are determined to change in two stages.

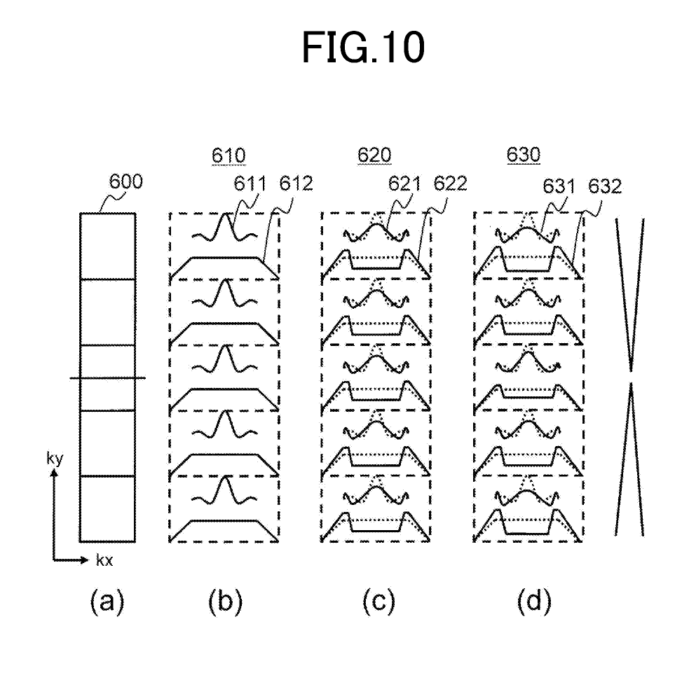

Next, a specific example of a VERSE pulse designed by the VERSE pulse design part 152 of the present embodiment will be described. FIGS. 10(a) to 10(d) are explanatory diagrams for explaining examples of VERSE pulse compression by the VERSE pulse design part 152 of the present embodiment. Here, a case where the phase-encoding step number Np is 5 is exemplified. The phase-encoding step number Np is not limited to this.

FIG. 10(a) shows the k-space 600. FIG. 10(b) shows an example (the case 610) of applying the RF pulse 611 whose compression rate is 0 i.e., an ideal initial setting and the Gs pulse 612 regardless of the phase-encoding amount.

FIG. 10(c) shows an example (the case 620) where a VERSE pulse compression rate (the RF pulse 621 and the Gs pulse 622) is set to a certain value other than 0 regardless of the phase-encoding amount. In this case, although slice profiles are the same in any of phase-encoding amounts, the profiles collapse by a compressed amount. Therefore, an echo signal having collapsed slice profiles is disposed even in a low-frequency region of k-space, which greatly affects image quality.

FIG. 10(d) shows an example (the case 630) of VERSE pulse compression of the present embodiment. As described above, a compression rate is changed according to the phase-encoding amount in the present embodiment. Deformation of the RF pulse 631 and the Gs pulse 632 is minimized by reducing a compression rate to the minimum in a phase-encoding amount of which a position to dispose an echo signal is in the vicinity of the k-space center. On the other hand, the compression rate is increased as being distant from the k-space center, which increases the deformation of these pulses.

In the present embodiment, thus, a VERSE pulse compression rate is determined, and an error effect of a GS pulse shape caused in an echo signal disposed in the vicinity of the k-space center is reduced. Also, by reducing a compression rate of a Gs pulse to be disposed in a low-frequency region of k-space, the band width in a low-frequency region of k-space is maintained, and a chemical shift effect is reduced, which results in a robust state in an off-resonance manner. Also, as being a higher range inversely, a VERSE pulse compression rate is increased, which obtains an effect such as SAR reduction. Thus, an SAR is reduced while image quality deterioration due to VERSE is minimized.

<Imaging Process Flow>

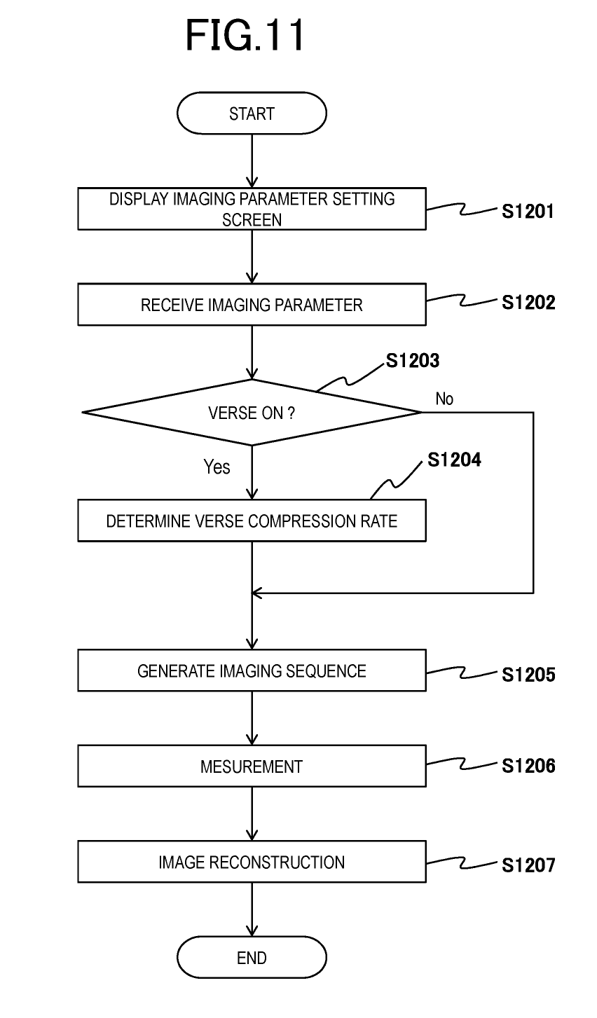

Lastly, an imaging process by the main control unit 132 of the present embodiment will be described. FIG. 11 is a process flow of the imaging process of the present embodiment. The imaging process of the present embodiment starts after a start-up command by a user.

After receiving the start-up command by a user, the imaging parameter setting support section 141 of the present embodiment displays the imaging parameter setting screen 200 on the display of the input/output device 133 (Step S1201).

When receiving a command to start imaging from a user, the imaging sequence generation section 142 receives imaging parameters input by the user through the imaging parameter setting screen 200 (Step S1202). Then, whether or not a command to use the VERSE method is received (VERSE ON or OFF) is determined (Step S1203).

In case of VERSEON, the imaging sequence generation section 142 allows the VERSE pulse design part 152 to determine a VERSE pulse compression rate identified with an imaging parameter input by a user (Step 1204), reflects the determination results, and then generates an imaging sequence (Step S1205).

On the other hand, in case of VERSE OFF in Step S1203, the imaging sequence generation section 142 proceeds to Step S1205 to generate an imaging sequence using shapes of an RF pulse and a Gs pulse identified with an imaging parameter input by a user as is.

The imaging section 143 provides a command to the sequencer 131 according to the generated sequence, executes measurement (Step S1206), and then reconstructs an image from an echo signal obtained in the measurement (Step S1207). The main control unit 132 ends an imaging process.

As described above, the MRI apparatus 100 of the present embodiment is provided with the imaging sequence generation section 142 that generates an imaging sequence by applying an imaging condition to a predetermined pulse sequence and the imaging section 143 that executes measurement according to the imaging sequence to reconstruct an image from the obtained echo signal. The pulse sequence includes a VERSE (Variable rate selective excitation) pulse comprised of a high-frequency magnetic field pulse and a slice selective gradient magnetic field pulse. The imaging sequence generation section 142 is provided with the VERSE pulse design part 152 that determines a compression rate of the VERSE pulse according to the predetermined imaging condition and applies the determined compression rate when generating the imaging sequence.

At this time, the imaging condition is a phase-encoding amount to be applied immediately after the VERSE pulse, and the VERSE pulse design part 152 determines a compression rate of the VERSE pulse immediately before applying a first of the phase-encoding amount so that the compression rate is larger than a compression rate of the VERSE pulse immediately before applying a second phase-encoding amount smaller than the first phase-encoding amount.

For example, the larger the phase-encoding amount, the compression rate is increased.

Therefore, according to the present embodiment, a VERSE pulse compression rate is changed according to the phase-encoding amount to perform imaging. At this time, when data of a low-frequency region in the vicinity of the k-space center is acquired, a VERSE pulse compression rate is reduced, and then pulse shape deformation is reduced. Hence, when the data of the low-frequency region having a great effect on image quality is acquired, a robust state in an off-resonance manner is achieved (it becomes difficult to shift a resonance frequency). On the other hand, when data of a high-frequency region is acquired, increasing a VERSE pulse compression rate and reducing an RF pulse amplitude contribute to SAR reduction. Hence, the off-resonance effect is alleviated, which can provide an image with a better SNR and contrast. That is, according to the present embodiment, an SAR can be reduced while image quality is maintained.

Additionally, in case of a pulse sequence including also slice encoding, a compression rate may be changed similarly to the above according to the slice-encoding amount.

### Third Embodiment

Next, the third embodiment of the present invention will be described. A VERSE pulse compression rate is determined according to the slice position in the first embodiment or according to the phase-encoding amount in the second embodiment. In the present embodiment, a VERSE pulse compression rate is determined according to the pulse type of an RF pulse to be applied in a pulse sequence.

The MRI apparatus of the present invention has a similar configuration to the MRI apparatus 100 of the first embodiment basically. However, as described above, because conditions for determining a VERSE pulse compression rate are different, processes of the imaging sequence generation section 142 are different. Hereinafter, different configurations from the first embodiment will be mainly described for the present embodiment.

The present embodiment includes a 90-degree pulse (excitation pulse) and 180-degree pulse (refocus pulse), and a pulse sequence for obtaining a spin echo is used. Hereinafter, in the present embodiment, the description will be made by taking a case of using an FSE sequence in a pulse sequence for obtaining a spin echo in order to change a VERSE pulse compression rate with an excitation pulse and refocus pulse as an example. Additionally, a pulse sequence that can be used for the present embodiment is not limited to the FSE sequence. For example, an SE sequence or SEEPI sequence may be used. Hereinafter, in the present embodiment, a VERSE pulse in which an RF pulse is an excitation pulse is referred to as an excitation VERSE pulse, and a VERSE pulse in which an RF pulse is a refocus pulse is referred to as a refocus VERSE pulse.

The imaging sequence generation section 142 of the present embodiment, similarly to the first embodiment, applies an imaging parameter to a predetermined pulse sequence (in this section, the above pulse sequence) to generate an imaging sequence. The imaging parameter to be used is that input by a user through the above imaging parameter setting screen 200.

The imaging sequence generation section 142 of the present embodiment, similarly to the first embodiment, is provided with the VERSE pulse design part 152 that determines a VERSE pulse compression rate according to the predetermined imaging condition when a user specifies a measurement by the VERSE method (VERSE ON). In the present embodiment, the imaging condition is a pulse type (FA?) of the RF pulse of the VERSE pulse. The VERSE pulse design part 152 of the present embodiment determines a VERSE pulse compression rate for each pulse type of the RF pulse. At this time, a compression rate of an excitation VERSE pulse is set smaller than that of a refocus VERSE pulse.

As described above, the linearity of a Gs pulse is not maintained in a position distant form the magnetic field center. Therefore, in a region distant form the magnetic field center in the Gs pulse application direction, tissue in a position different from the original target is excited, and a signal from the region becomes an artifact.

In an imaging sequence for obtaining a spin echo, if waveforms of a Gs pulse to be applied at the same time as an excitation pulse (90-degree pulse) and that to be applied at the same time as a refocus pulse (180-degree pulse) are the same, the Gs pulses lose linearity similarly. Therefore, a region different form the target is respectively excited and refocused, and a signal is generated from the region.

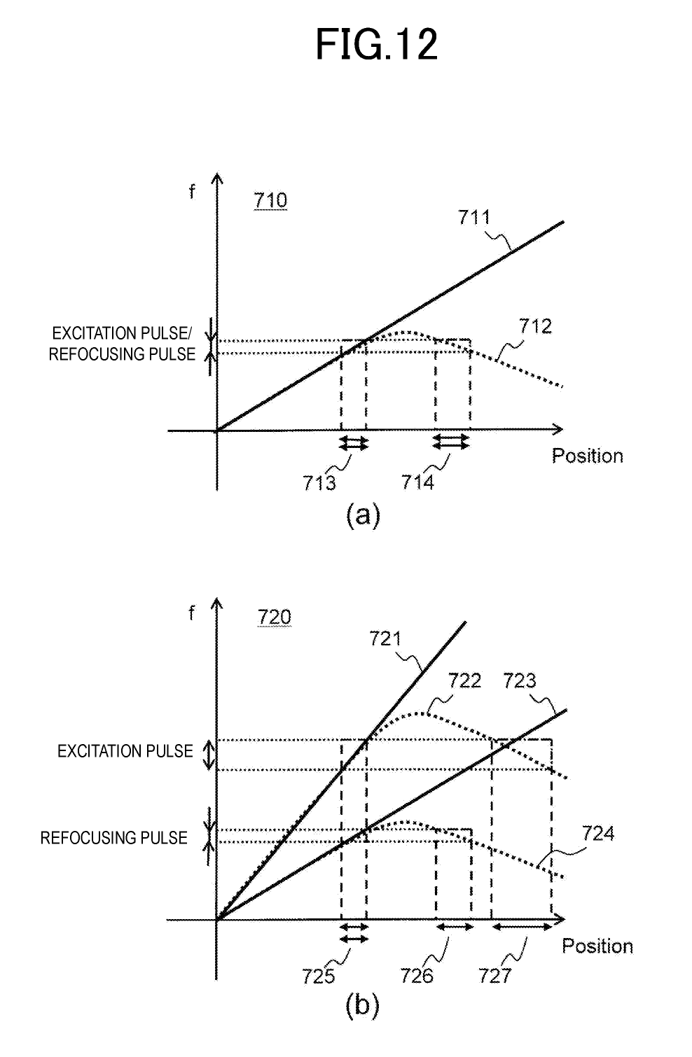

FIG. 12(a) shows a position to be excited and refocused in a case where compression rates of a excitation VERSE pulse and refocus VERSE pulse are equal (the case 710). Additionally, in the present diagram, the vertical axis shows a frequency, and the horizontal axis shows an excitation position.

Although a Gs pulse frequency change according to the excitation position is ideally the linearity 711 as shown in the present diagram, the linearity is not maintained actually in a position distant from the magnetic field center as shown in the dotted line 712.

In the case 710, because irradiation frequencies and band widths of the excitation pulse and refocus pulse are respectively the same, the region (714) different from the targeted region (713) is also excited and refocused, which results in obtaining a signal from the region too. Therefore, when the same compression rate is set for the excitation VERSE pulse and the refocus VERSE pulse, an artifact caused by a signal from a position different from the target is generated similarly.

In order to avoid this, respectively different compression rates are applied to an excitation VERSE pulse and a refocus VERSE pulse in the present embodiment. Hence, behaviors in non-linear regions of the respective Gs pulses are configured so as to differ from each other in order to avoid being excited and refocused in a position other than the target.

Additionally, both the compression rates are determined so as to excite and refocus a target position. Specifically, the compression rates are determined so that intensities of a Gs pulse to be applied with an excitation pulse and a Gs pulse to be applied with a refocus pulse differ from each other.

FIG. 12(b) shows the excitation and refocus positions in a case of changing a compression rate of an excitation VERSE pulse and a refocus VERSE pulse (the case 520). Also in the present diagram, the vertical axis shows a frequency, and the horizontal axis shows an excitation position.

When a compression rate is changed between an excitation VERSE pulse and a refocus VERSE pulse, frequency states according to the excitation positions of the respective Gs pulses are also changed as shown in the present diagram. In the diagram, an ideal Gs pulse is shown in the solid line 721, and the actual Gs pulse is shown in the dotted line 722. Also, an ideal state of a Gs pulse of a refocus VERSE pulse is shown in the solid line 723, and the actual state is shown in the dotted line 724.

The compression rate is adjusted so that the target region 725 is excited and refocused. By adjusting the compression rate, a gradient of a Gs pulse is changed.

Additionally, as shown in the present diagram, the region 726 is excited, and the region 727 is refocused because there are regions where Gs pulse changes are not linear. However, because these two regions (726 and 727) do not correspond to each other, a signal from a position other than the target is alleviated compared to the case 710, which reduces artifacts.

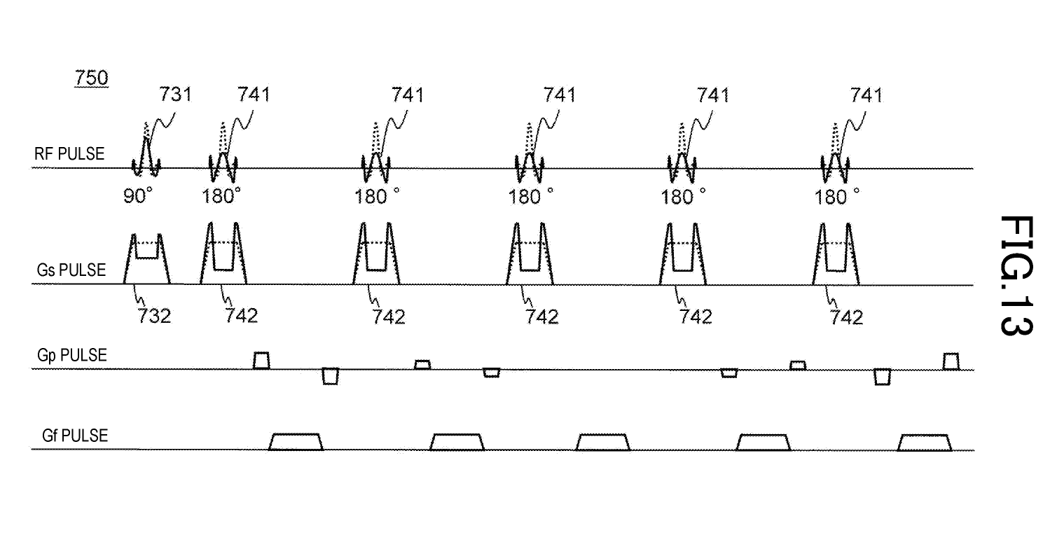

Next, a specific example of a VERSE pulse designed by the VERSE pulse design part 152 of the present embodiment will be described. FIG. 13 is an explanatory diagram for explaining an example of the VERSE pulse compression by the VERSE pulse design part 152 of the present embodiment. In the diagram, the shown example is a case of assuming a pulse sequence as a sequence for obtaining a spin echo and an FSE sequence in which a plurality of refocus pulses are applied after excitation pulse application. In the shown example, the number of refocus pulses is 5. In FIG. 13, the dotted lines show the RF pulse and Gs pulse before compression, and the solid lines show the RF pulse and Gs pulse after being compressed at a compression rate determined by the VERSE pulse design part 152.

As shown in the present diagram, in an excitation VERSE pulse (the RF pulse 731 and the Gs pulse 732), change by VERSE is reduced in order to minimize a collapse of a slice profile shape. That is, a compression rate is set small. Hence, a favorable slice profile is maintained. On the other hand, in a refocus VERSE pulse (the RF pulse 741 and the Gs pulse 742), a compression rate is set large in order to reduce SAR. The compression rate is set as above.

<Imaging Process Flow>

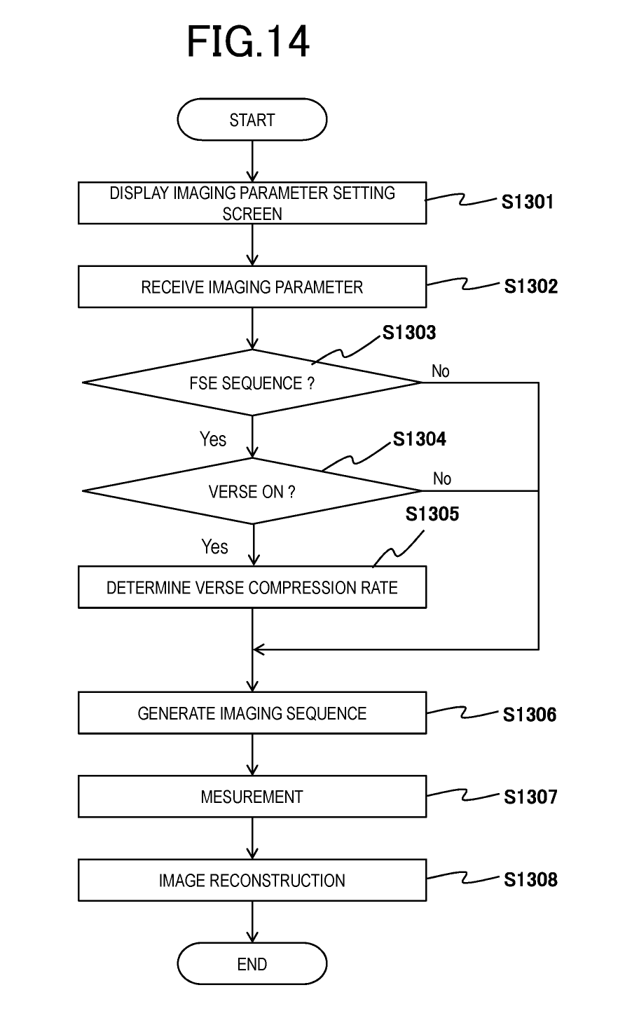

Lastly, an imaging process by the main control unit 132 of the present embodiment will be described. FIG. 14 is a process flow of the imaging process of the present embodiment. The imaging process of the present embodiment starts after a start-up command by a user.

After receiving the start-up command by a user, the imaging parameter setting support section of the present embodiment displays the imaging parameter setting screen 200 on the display of the input/output device 133 (Step S1301).

When receiving a command to start imaging from a user, the imaging sequence generation section 142 receives an imaging parameter input by the user through the imaging parameter setting screen 200 (Step S1302). Then, whether or not a sequence used for measurement is an FSE sequence is determined (Step S1303). Then, in case of the FSE sequence, whether or not a command to use the VERSE method is received (VERSE ON or OFF) is determined (Step S1304).

In case of VERSE ON, the imaging sequence generation section 142 allows the VERSE pulse design part 152 to determine a VERSE pulse compression rate identified with an imaging parameter input by a user (Step S1305) and reflects the determination results to generate an imaging sequence (Step S1306).

On the other hand, if it is not an FSE sequence in Step S1303 and in case of VERSE OFF in Step S1304, the imaging sequence generation section 142 proceeds to Step 1306 and uses shapes of an RF pulse and Gs pulse identified with an imaging parameter input by a user as is to generate an imaging sequence.

The imaging section 143 provides commands to the sequencer 131 according to the generated imaging sequence, executes measurement (Step S1307), and then reconstructs an image from an echo signal obtained by the measurement (Step S1308). Then, the main control unit 132 ends the imaging process.

As described above, the MRI apparatus 100 of the present embodiment is provided with the imaging sequence generation section 142 that generates an imaging sequence by applying an imaging condition to a predetermined pulse sequence and the imaging section 143 that executes measurement according to the imaging sequence to reconstruct an image from the obtained echo signal, the pulse sequence includes a VERSE (Variable rate selective excitation) pulse comprised of a high-frequency magnetic field pulse and a slice selective gradient magnetic field pulse, and the imaging sequence generation section 142 is provided with the VERSE pulse design part 152 that determines a compression rate of the VERSE pulse according to the predetermined imaging condition and applies the determined compression rate when generating the imaging sequence.

At this time, the pulse sequence is an FSE sequence, the imaging condition is a pulse type of the RF pulse of the VERSE pulse. The VERSE pulse design part 152 sets a compression rate of the VERSE pulse in which the pulse type is an excitation pulse smaller than a compression rate of the VERSE pulse in which the pulse type is a refocus pulse.

Thus, according to the present embodiment, a VERSE pulse compression rate is changed using an excitation VERSE pulse and a refocus VERSE pulse. In the excitation VERSE pulse having a great effect on image quality, a compression rate is reduced to minimize a collapse of a slice profile shape. On the other hand, in a refocus VERSE pulse, a compression rate is increased to reduce an SAR. Hence, the slice profile can be improved, and artifacts caused by signals in a region where the linearity of a gradient magnetic field collapses can be reduced. That is, according to the present embodiment, an SAR can be reduced while image quality deterioration due to VERSE is minimized.

Additionally, although compression rates of the respective refocus VERSE pulses are the same even in a case where there are a plurality of refocus VERSE pulses in the above embodiment, the compression rates may be changed even in the refocus VERSE pulses.

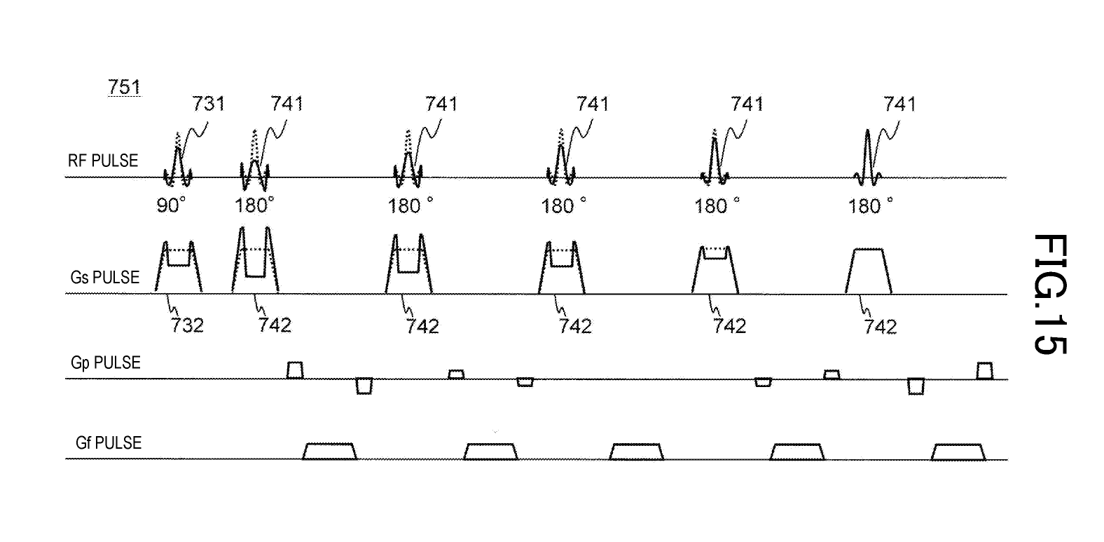

A compression example of the VERSE pulses in this case is shown in FIG. 15. Here, a compression rate of a refocus VERSE pulse (the RF pulse 741 and the Gs pulse 742) is set larger than that of an excitation VERSE pulse (the RF pulse 731 and the Gs pulse 732) similarly to the above. Additionally, a compression rate is changed according to the application timing in the plurality of refocus VERSE pulses. Here, the compression rate is changed gradually with the lapse of time. That is, a compression rate of the VERSE pulse of a refocus pulse to be applied at a first application timing is determined smaller than that of the VERSE pulse of a refocus pulse to be applied at a second application timing before the first application timing. For example, the later the application timing of the refocus VERSE pulse, the compression rate is reduced.

By determining a compression rate thus, the latter half of slice profiles of a refocus VERSE pulse becomes more favorable. If a refocus pulse with a high compression rate and unfavorable slice profiles continues to be applied to a region where an excitation pulse was applied, small excitation outside the region where an excitation pulse was applied is accumulated and appears as a signal. However, according to the present embodiment, the effect on the outside of the region excited by the excitation pulse can be reduced, which can prevent the error accumulation.

Additionally, the compression rate determination methods of the above respective embodiments can be used in combination with each other. For example, when a pulse sequence is an FSE sequence, a compression rate may be changed according to the RF pulse type as well as the phase-encoding amount. Additionally, in case of multi-slice imaging, the compression rate may be changed according to the slice position.

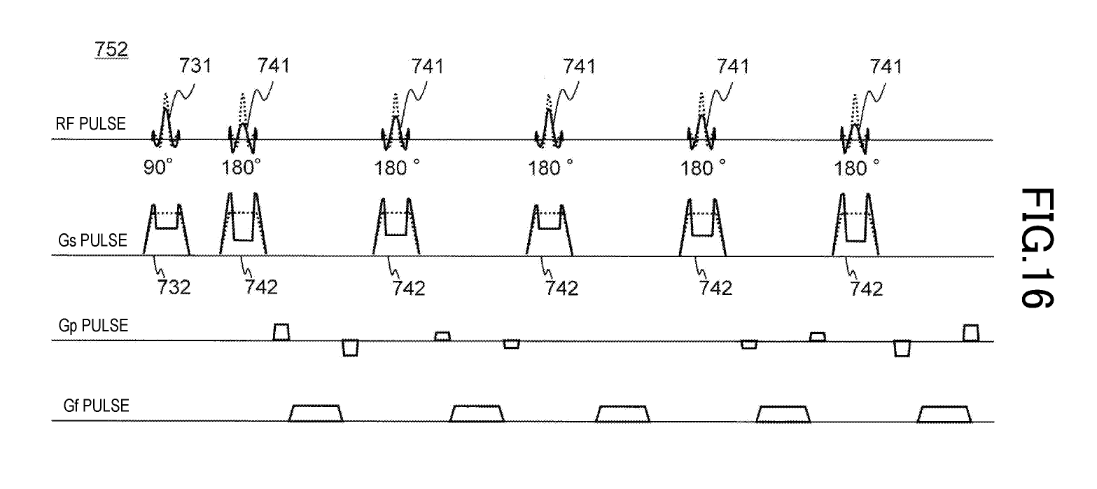

FIG. 16 shows a pulse sequence example in a case where a compression rate of an excitation VERSE pulse and a refocus VERSE pulse is changed in the manner of the third embodiment using an FSE sequence and a compression rate of a refocus VERSE pulse is additionally changed in the manner of the second embodiment according to the phase-encoding amount.

As shown in the present diagram, a compression rate of a refocus VERSE pulse (the RF pulse 741 and the Gs pulse 742) is set larger than that of an excitation VERSE pulse (the RF pulse 731 and the Gs pulse 732) similarly to the above. Additionally, a compression rate is changed according to the phase-encoding amount to be applied immediately after in a plurality of refocus VERSE pulses.

Additionally, it may be configured so that a compression rate of an excitation VERSE pulse and a refocus VERSE pulse is set smaller as a slice position becomes farther from the magnetic field center.

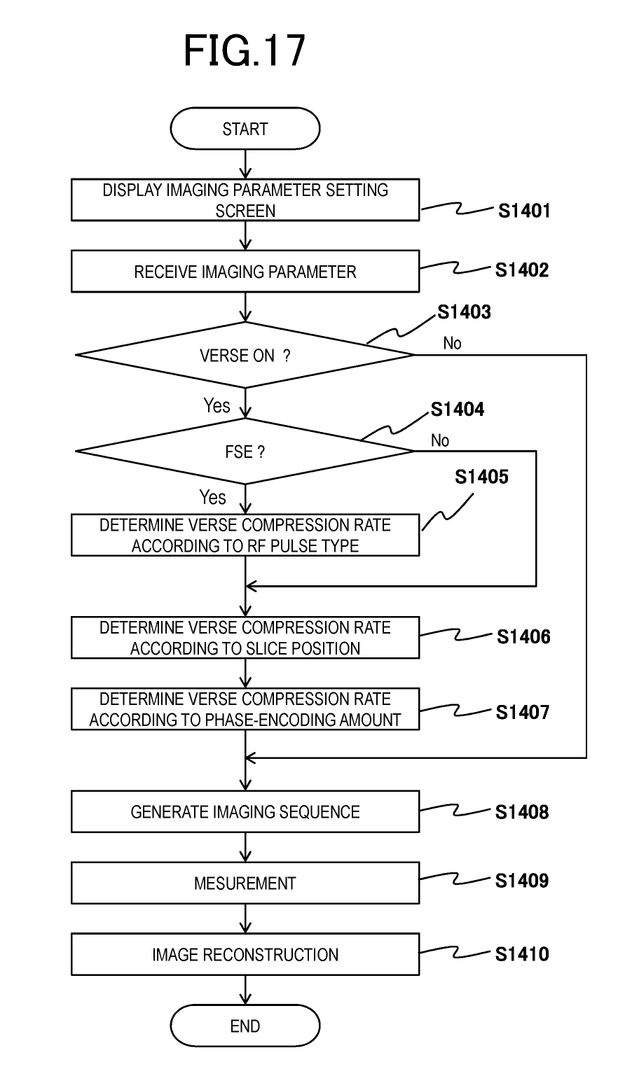

FIG. 17 shows a process flow of the imaging process in a case where the three methods are used in combination with each other. Also in this case, the process starts after a start-up command by a user.

When receiving a start-up command by a user, the imaging parameter setting support section of the present embodiment displays the imaging parameter setting screen 200 on the display of the input/output device 133 (Step S1401).

When receiving a command to start imaging from a user, the imaging sequence generation section 142 receives an imaging parameter input by the user though the imaging parameter setting screen 200 (Step S1402). Then, the imaging sequence generation section 142 determines whether or not a command to use the VERSE method is received (VERSE ON or OFF) (Step S1403). If received, whether or not the pulse sequence is a sequence for obtaining a spin echo (for example, FSE) is determined (Step S1404). If it is not FSE, the process proceeds to Step S1406 to be described later.

Then, if it is FSE, the imaging sequence generation section 142 allows the VERSE pulse design part 152 to determine compression rates of an excitation VERSE pulse and a refocus VERSE pulse respectively based on the other parameters set by a user (Step S1405).

Next, the imaging sequence generation section 142 allows the VERSE pulse design part 152 to determine compression rates of a VERSE pulse respectively according to the distance from the magnetic field center of a slice based on the other parameters set by a user (Step S1406).

Thereafter, the imaging sequence generation section 142 allows the VERSE pulse design part 152 to determine a VERSE pulse compression rate according to the phase-encoding amount (Step S1407) and reflects the determined compression rate on the VERSE pulse in a pulse sequence to generate an imaging sequence (Step S1408).

The imaging section 143 executes measurement according to the imaging sequence generated by the imaging sequence generation section 142 (Step S1409) and reconstructs an image from an echo signal obtained by the measurement (Step S1410). Then, the main control unit 132 ends the imaging process.

Additionally, although the processes are performed in the order of determining a compression rate according to the pulse type, determining a compression rate according to the slice position, and determining a compression rate according to the phase-encoding amount in the above embodiment, the processing order is not limited to this. Any of the processes may be performed first.

### DESCRIPTION OF REFERENCE NUMERALS

100: MRI apparatus
101: object
110: gantry
111: static magnetic field
112: gradient magnetic field coil
113: irradiation coil
114: reception coil
120: drive system
121: X-axis gradient magnetic field power source
122: Y-axis gradient magnetic field power source
123: Z-axis gradient magnetic field power source
124: transmission system
125: reception system
130: control system
131: sequencer
132: main control unit
133: input/output device
141: imaging parameter setting support section
142: imaging sequence generation section
143: imaging section
152: VERSE pulse design part
200: imaging parameter setting screen
201: patient information display region
202: first input region
203: second input region
204: imaging control region
205: VERSE command region
206: sequence receiving region
311: RF pulse
312: Gs pulse
313: output Gs pulse
314: slice profile
321: RF pulse
322: Gs pulse
323: output Gs pulse
324: slice profile
331: RF pulse
332: Gs pulse
333: output Gs pulse
334: slice profile
411: compression rate transition graph
412: compression rate transition graph
413: compression rate transition graph
414: compression rate transition graph
421: compression rate transition graph
422: compression rate transition graph
423: compression rate transition graph
424: compression rate transition graph
511: RF pulse
512: Gs pulse
514: slice profile
521: RF pulse
522: Gs pulse
524: slice profile
531: RF pulse
532: Gs pulse
534: slice profile
541: RF pulse
542: Gs pulse
544: slice profile
600: k-space
611: RF pulse
612: Gs pulse
621: RF pulse
622: Gs pulse
631: RF pulse
632: Gs pulse
711: ideal Gs pulse
712: actual Gs pulse
713: excitation/refocus region
714: excitation/refocus region
721: ideal Gs pulse
722: actual Gs pulse
723: ideal Gs pulse
724: actual Gs pulse
725: excitation/refocus region
726: refocus region
727: excitation region
731: RF pulse
732: Gs pulse
741: RF pulse
742: Gs pulse

1. A magnetic resonance imaging apparatus comprising:
an imaging sequence generation section that generates an imaging sequence by applying an imaging condition to a predetermined pulse sequence; and
an imaging section that executes measurement according to the imaging sequence to reconstruct an image from the obtained echo signal,
wherein the pulse sequence includes a VERSE (Variable rate selective excitation) pulse comprised of a high-frequency magnetic field pulse and a slice selective gradient magnetic field pulse, and
the imaging sequence generation section is provided with a VERSE pulse design part for determining a compression rate of the VERSE pulse according to the imaging condition and applies the determined compression rate to generate the imaging sequence.

2. The magnetic resonance imaging apparatus according to claim 1,
wherein the imaging condition is a slice position selected by the VERSE pulse, and
the VERSE pulse design part determines a compression rate of the VERSE pulse selecting a slice position whose distance from the magnetic field center is a first distance so that the compression rate is smaller than a compression rate of the VERSE pulse selecting a slice position of a second distance whose distance from the said magnetic field center is closer than the first distance.

3. The magnetic resonance imaging apparatus according to claim 1,
wherein the imaging condition is a phase-encoding amount to be applied immediately after the VERSE pulse, and
the VERSE pulse design part determines a compression rate of the VERSE pulse immediately before applying a first phase-encoding amount so that the compression rate is larger than a compression rate of the VERSE pulse immediately before applying a second phase-encoding amount smaller than the first phase-encoding amount.

4. The magnetic resonance imaging apparatus according to claim 1,
wherein the pulse sequence is a sequence comprises an excitation pulse and a refocus pulse to obtain a spin echo,
the imaging condition is a pulse type of the high-frequency magnetic field pulse of the VERSE pulse, and
the VERSE pulse design part determines a compression rate of the VERSE pulse in which the pulse type is the excitation pulse smaller than a compression rate of the VERSE pulse in which the pulse type is the refocus pulse.

5. The magnetic resonance imaging apparatus according to claim 4,
wherein the VERSE pulse design part determines a compression rate of a VERSE pulse to be applied at a first application timing in the VERSE pulse in which the pulse type is the refocus pulse so that the compression rate is smaller than that of the VERSE pulse to be applied at a second application timing before the first application timing.

6. The magnetic resonance imaging apparatus according to claim 4,
wherein the VERSE pulse design part determines a compression rate of a VERSE pulse immediately before applying a first phase-encoding amount in the VERSE pulse in which the pulse type is the refocus pulse so that the compression rate is larger than that of the VERSE pulse immediately before applying a second phase-encoding amount smaller than the first phase-encoding amount.

7. The magnetic resonance imaging apparatus according to claim 6,
wherein the VERSE pulse design part further determines a compression rate of the VERSE pulse selecting a slice position whose distance from the magnetic field center is a first distance so that the compression rate is smaller than a compression rate of the VERSE pulse selecting a slice position of a second distance whose distance from the said magnetic field center is closer than the first distance.

8. The magnetic resonance imaging apparatus according to claim 2,
wherein either of a change rate or a change amount of the compression rate between the slice positions is constant.

9. The magnetic resonance imaging apparatus according to claim 2,
wherein the compression rate changes stepwise according to the distance from the said magnetic field center in the slice position.

10. The magnetic resonance imaging apparatus according to claim 3,
wherein either of a change rate or a change amount of the compression rate between phase-encoding steps is constant.

11. The magnetic resonance imaging apparatus according to claim 3,
wherein the compression rate changes stepwise according to the phase-encoding amount.

12. The magnetic resonance imaging apparatus according to claim 1,
wherein the imaging sequence generation section receives a command of whether or not to compress the VERSE pulse from a user, and
the VERSE pulse design part determines the compression rate according to the imaging condition in case of receiving a command to compress.

13. The magnetic resonance imaging apparatus according to claim 12, further comprising:
an imaging parameter setting support section that allows displaying an imaging parameter setting screen to support input of the imaging condition by a user,
wherein the imaging sequence generation section receives a command of whether or not to compress the VERSE pulse through the imaging parameter setting screen.

14. A magnetic resonance imaging method,
wherein a compression rate of a VERSE (Variable rate selective excitation) pulse comprised of a high-frequency magnetic field pulse and a slice selective gradient magnetic field pulse is determined according to the imaging condition,
an imaging sequence is generated by applying the determined compression rate to the VERSE pulse of a pulse sequence comprising the VERSE pulse, and
an image is reconstructed from the echo signal obtained by executing measurement according to the generated imaging sequence.

15. A VERSE pulse compression rate determination method determining a VERSE pulse compression rate using at least any one of the following:
setting a compression rate of the VERSE (Variable rate selective excitation) pulse selecting a slice position whose distance from the magnetic field center is a first distance so that the compression rate is smaller than a compression rate of the VERSE pulse selecting a slice position of a second distance whose distance from the said magnetic field center is closer than the first distance;
setting a compression rate of the VERSE pulse immediately before applying a first phase-encoding amount so that the compression rate is larger than a compression rate of the VERSE pulse immediately before applying a second phase-encoding amount smaller than the first phase-encoding amount; and
setting a compression rate of the VERSE pulse in which a pulse type of a high-frequency magnetic field pulse is an excitation pulse so that the compression rate is smaller than a compression rate of the VERSE pulse in which the pulse type is a refocus pulse in a case where a pulse sequence is a sequence for obtaining a spin echo.
